(19) United States
(12) Patent Application Publication
(10) Pub. No.: US 2015/0228629 A1
(43) Pub. Date: Aug. 13, 2015

(54) DIMMABLE LIGHT-EMITTED DIODE (LED) PACKAGING STRUCTURE

(71) Applicant: EDISON OPTO CRPORATION, New Taipei City (TW)

(72) Inventors: Shang-Hsun Tsai, New Taipei City (TW); Chien-Jung Wu, New Taipei City (TW)

(73) Assignee: EDISON OPTO CRPORATION, New Taipei City (TW)

(21) Appl. No.: 14/275,022

(22) Filed: May 12, 2014

(30) Foreign Application Priority Data
Feb. 10, 2014 (TW) 103104284

(51) Int. Cl. H01L 25/075; H01L 33/52; H01L 33/50

(52) U.S. Cl. CPC H01L 25/0753; H01L 33/507; H01L 33/52; H01L 33/504

(57) ABSTRACT

A dimmable light-emitted diode (LED) packaging structure is described. The dimmable LED packaging structure employs a plurality of first fluorescent layers respectively positioned on some of a plurality of first types of LED chips to solve the problems of color temperature and light mixing uniformity. Further, a second fluorescent layer overlays the first fluorescent layers and a potion of the first types of LED chips to simplify the manufacturing step of dimmable LED packaging structure.

### FIELD OF THE INVENTION

The present invention relates to a light-emitted diode (hereinafter LED), and more particularly to a dimmable LED.

### BACKGROUND OF THE INVENTION

FIG. 1 is a conventional LED packaging structure. The LED packaging structure is configured to be a chip-on-board (COB) packaging structure and includes a substrate 100, a plurality of LED chips 102 disposed on the substrate 100, and the phosphor glue 104 filled within the sidewall 103 for overlaying the LED chips 102, wherein the phosphor glue 104 composed of phosphor powder includes the fluorescent glue with warm white and cold white characteristics.

As shown in FIG. 1, the LED packaging structure is made of a light-mixed manner by the phosphor powder with two different concentrations, i.e. phosphor glue with warm white characteristic 104a and phosphor glue with cold white characteristic 104b, to perform a glue-dispensing process. After the process of chip attachment and wire bonding are complete, the phosphor glue 104 in different proportions arrangements is packaged in the different warm white and cold white regions respectively for dispensing the glue to meet the different requirements of color temperatures. Although the color temperature of the LED packaging structure can be changed, it is necessary to enclose the phosphor glue 104 by using a light cover to form a light-mixed chamber (not shown) above the substrate 100. In this manner, it is required to construct a larger space for the light-mixed condition, which results in uneven light-mixed status of the LED chips 102 in the different warm white and cold white regions respectively. Moreover, it is demanded to perform disadvantageously two processes of glue dispensation of the warm white characteristic 104a and phosphor glue with cold white characteristic 104b in the different warm white and cold white regions, which are complicated manufacturing steps.

Consequently, there is a need to develop a novel LED packaging structure to solve the problems of color temperature irregular change, uneven light-mixed situation and manufacturing complicated steps in the aforementioned descriptions.

### SUMMARY OF THE INVENTION

One objective of the present invention is to provide a dimmable light-emitted diode (LED) packaging structure by employing a plurality of first fluorescent layers disposed on one portion of the first types of LED chips correspondingly to solve the problems of color temperature irregular change and uneven mixing-light.

Another objective of the present invention is to provide a dimmable LED packaging structure by employing a second fluorescent layer for overlaying the first fluorescent layers and the other portion of the first types of LED chips to solve the problem of complicated manufacturing steps.

According to the above objectives, the present invention sets forth a dimmable LED packaging structure. The dimmable LED comprises a substrate; an annual sidewall disposed on the substrate; a plurality of first types of LED chips disposed on the substrate within the annual sidewall, wherein each of the first types of LED chips emits a light ray; a plurality of first fluorescent layers disposed on one portion of the first types of LED chips correspondingly; and a second fluorescent layer filled within the annual sidewall for overlaying the first fluorescent layers and the other portion of the first types of LED chips, wherein when the one portion of the first types of LED chips emit the light rays through the first fluorescent layers and the second fluorescent layer and when the other portion of the first types of LED chips emit the light rays through the second fluorescent layer, the light rays on a surface of the first fluorescent layers are mixed with a surface of the other portion of the first types of LED chips for dimming the LED.

In one embodiment, the dimmable LED further comprises a plurality of second types of LED chips disposed on the substrate within the annual sidewall and staggered with the first types of LED chips. Each of the first types of LED chips is a blue LED chip and each of the second types of LED chips is a red LED chip. A ratio of an amount of the blue LED chips and an amount of the red LED chips is between one-to-one (1:1) and three-to-one (3:1). When each of the first types of LED chips is an LED chip with a vertical structure, an area of each of the first fluorescent layers is either less than or equal to an area of the LED chip with the vertical structure. Further, when each of the first types of LED chips is an LED chip with a horizontal structure, an area of each of the first fluorescent layers is either greater than or equal to an area of the LED chip with the horizontal structure.

An area of each of the first fluorescent layers is 0.8 time to 2 times an area of the first types of LED chips. Each of the first fluorescent layers is a phosphor sheet with warm white characteristic. A bottom surface of each of the first fluorescent layers further comprises a laminating layer for adhering the first fluorescent layers to the one portion of the first types of LED chips correspondingly. The second fluorescent layer is phosphor glue with cold white characteristic.

According to the above-mentioned descriptions, the dimmable LED packaging structure employs a plurality of first fluorescent layers disposed on one portion of the first types of LED chips correspondingly to solve the problems of color temperature irregular change and uneven mixing-light, and employs a second fluorescent layer for overlaying the first fluorescent layers and the other portion of the first types of LED chips to solve the problem of complicated manufacturing steps.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a conventional LED packaging structure;

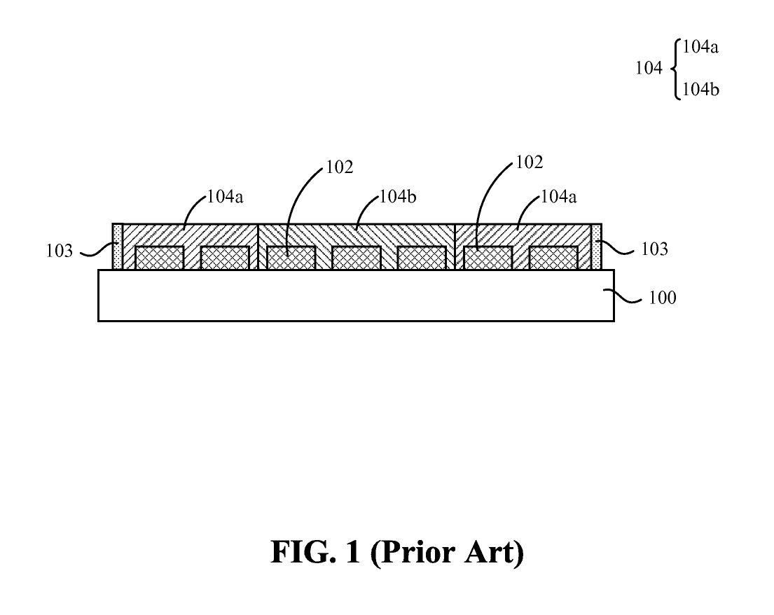

FIG. 2 is a schematic top view of LED packaging structure according to one embodiment of the present invention;

FIG. 3 is a cross-sectional view of the LED packaging structure along the line A-A′ in FIG. 2 according to one embodiment of the present invention;

FIG. 4 is a schematic view of the wiring arrangement of the LED packaging structure according to one embodiment of the present invention; and

FIG. 5 is a schematic view of the wiring arrangement of the LED packaging structure according to another embodiment of the present invention.

### DETAILED DESCRIPTION OF THE PREFERRED EMBODIMENTS

The dimmable LED packaging structure in the present invention employs the annual sidewall to form a chip attachment region compose of an area with cold white characteristic and an area with warm white characteristic wherein the area with cold white characteristic includes blue LED chips without phosphor sheets with warm white characteristic and the area with warm white characteristic includes blue LED chips with phosphor sheets with warm white characteristic. In other words, the phosphor sheets with warm white characteristic are attached to a portion of blue LED chips so that the area with cold white characteristic is staggered with the area with warm white characteristic for adjusting the color temperature of the dimmable LED packaging structure and for mixing uniformly the light rays between the area with cold white characteristic and the area with warm white characteristic.

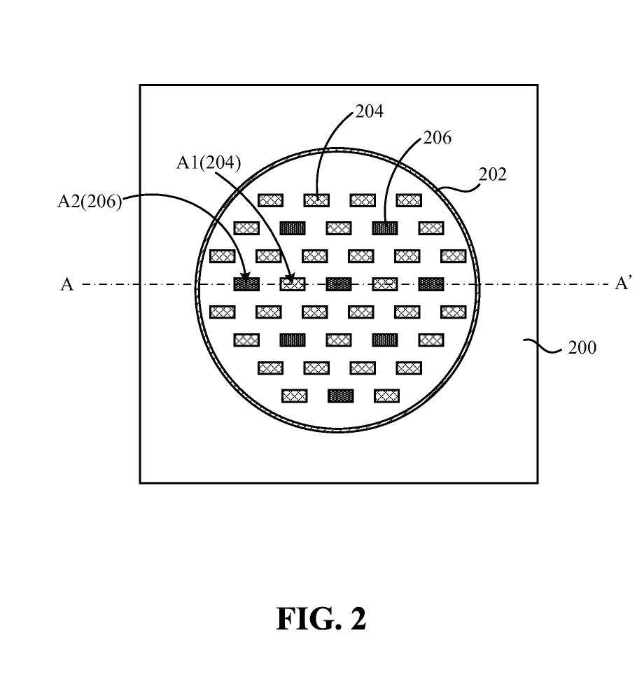

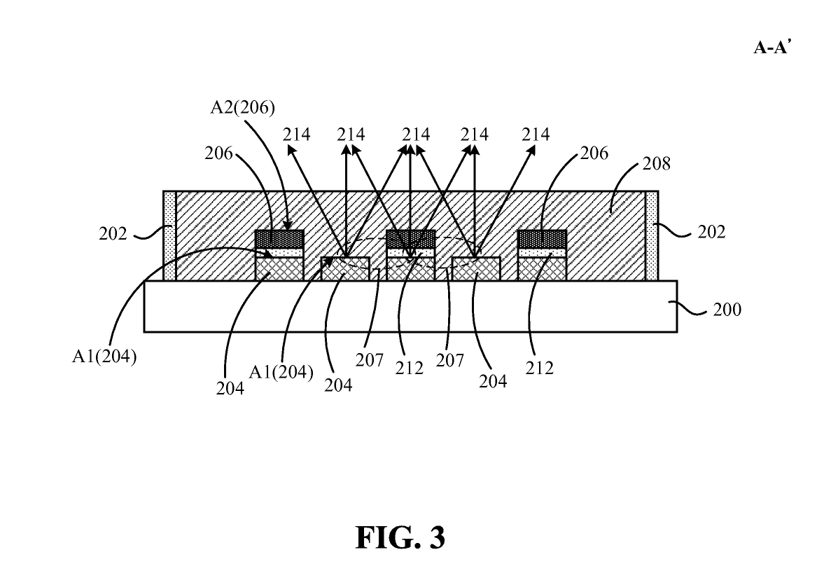

Please refer to FIG. 2 and FIG. 3. FIG. 2 is a schematic top view of LED packaging structure according to one embodiment of the present invention. FIG. 3 is a cross-sectional view of the LED packaging structure along the line A-A′ in FIG. 2 according to one embodiment of the present invention. As shown in FIG. 2 and FIG. 3, the dimmable LED packaging structure includes a substrate 200, an annual sidewall 202, a plurality of first types of LED chips 204, a plurality of first fluorescent layers 206, a second fluorescent layer 208 and a laminating layer 212.

In one case, the substrate 200 may be ceramic substrate with electrical insulation and is composed of ceramic material selected from one group consisting of aluminium oxide, aluminium nitride, zirconium oxide and calcium fluoride. The annual sidewall 202 disposed on the substrate 200 surrounds the first types of LED chips 204 so that the second fluorescent layer 208 overlays the first fluorescent layers 206 and the other portion of the first types of LED chips 204. The first types of LED chips 204 disposed on the substrate 200 within the annual sidewall 202, wherein each of the first types of LED chips 204 emits a light ray. In one embodiment, each of the first types of LED chips 204 is a blue LED chip.

As shown in FIG. 2 and FIG. 3, a plurality of first fluorescent layers 206 are disposed on one portion of the first types of LED chips 204 correspondingly. That is, the first fluorescent layers 206 are stacked on the top surface of the one portion of the first types of LED chips 204 so that the one portion of the first types of LED chips 204 sequentially are disposed on the first fluorescent layers 206 and the second fluorescent layer 208. In one embodiment, the bottom surface of each of the first fluorescent layers 206 further includes a laminating layer 212 for adhering the first fluorescent layers 206 to the surfaces of the one portion of the first types of LED chips 204 correspondingly. In one embodiment, the laminating layer 212 may be selected from the group consisting of silver glue, tin glue, speculum metal, and Au—Sn alloy and laminating layer 212 facilitates the thermal conductivity of the dimmable LED packaging structure.

Specifically, the first fluorescent layers 206 are coated on the one portion of the first types of LED chips 204 to serve as the fluorescent function of warm white characteristic (e.g. red color temperature) for converting the original light of the one portion of the first types of LED chips 204 into the light rays 214 with predetermined color temperature. For example, the ultraviolet ray is converted into the visible light with blue color and the visible light with blue color emits the first fluorescent layers 206 with warm color temperature to generate the light with warm white characteristic. In one preferred embodiment, each of the first fluorescent layers 206 is a phosphor sheet with warm white characteristic which are stacked on the one portion of the first types of LED chips 204 wherein the phosphor sheet with warm white characteristic is a red phosphor sheet.

In FIG. 2 and FIG. 3, the second fluorescent layer 208 is filled within the annual sidewall 202 for overlaying the first fluorescent layers 206 and the other portion of the first types of LED chips 204 and the second fluorescent layer 208 is filled to the spacer between the first types of LED chips 204 to serve as the fluorescent function of cold white characteristic (e.g. blue color temperature). For example, the second fluorescent layer 208 is the phosphor glue with clod white characteristic. Further, in one embodiment, the present invention fills the phosphor glue with clod white characteristic in the same concentration to the annual sidewall 202 for simplifying the manufacturing process of the dimmable LED packaging structure.

As shown in FIG. 3, when the one portion of the first types of LED chips 204 emit the light rays 214 through the first fluorescent layers 206 and the second fluorescent layer 208 and when the other portion of the first types of LED chips 204 emit the light rays 214 through the second fluorescent layer 208, the light rays 214 on a surface of the first fluorescent layers 206 are mixed with a surface of the other portion of the first types of LED chips 204 for dimming the LED.

Specifically, the first fluorescent layers 206 are disposed on the one portion of the first types of LED chips 204 respectively so that the first fluorescent layers 206 convert the light rays of the one portion of the first types of LED chips 204 into the light with warm white characteristic. The first fluorescent layers 206 are not disposed on the other portion of the first types of LED chips 204 so that the other portion of the first types of LED chips 204 directly forms the light rays with cold white characteristic. Since the two light rays with different color temperature are adjacent each other and the one portion of the first types of LED chips 204 having the first fluorescent layers 206 are adjoined to the other portion of the first types of LED chips 204 without the first fluorescent layer 206, the color temperature of the dimmable LED packaging structure can be adjusted to mix uniformly the light ray.

Moreover, in FIG. 2 and FIG. 3, the second fluorescent layer 208 is covered on the one portion of the first types of LED chips 204 having first fluorescent layers 206 thereon and the other portion of the first types of LED chips 204 without first fluorescent layers 206 thereon. Thus, the one portion of the first types of LED chips 204 having first fluorescent layers 206 thereon are staggered with the other portion of the first types of LED chips 204 without first fluorescent layers 206, and the second fluorescent layer 208 is covered with the first fluorescent layers 206 so that the light rays with warm color and cold color are mixed uniformly near the light emission region 207. In other words, the first types of LED chips 204 near the light emission region 207 are capable of adjusting the color temperature and mixing the light rays uniformly. For example, the one portion of the first types of LED chips 204 having first fluorescent layers 206 thereon and the other portion of the first types of LED chips 204 without first fluorescent layers 206 near the annual sidewall 202 can mix the light rays adequately such that the dimmable LED packaging structure can be adjusted to mix evenly the light ray.

Please continuously refer to FIG. 2 and FIG. 3. In one embodiment, when each of the first types of LED chips 204 is an LED chip with a vertical structure, an area A2 of each of the first fluorescent layers 206 is either less than or equal to an area A1 of the LED chip with the vertical structure wherein the two electrodes of the LED chip with the vertical structure are disposed in the two sides of the LED extension layer. The LED chip with the vertical structure is an opaque layer served as a lining layer and thus, the LED chip with the vertical structure is in opaque status such that the light is emitted from the surface of the chip and the light is blocked from the lateral side. Therefore, the area A2 of each of the first fluorescent layers 206 is either less than or equal to an area A1 of the LED chip with the vertical structure. In one preferred embodiment, the area A2 of each of the first fluorescent layers is 0.8 time to 1 time an area of the first types of LED chips with the vertical structure. In this case of FIG. 2 and FIG. 3, the area A1 is equal to the area A2.

In another embodiment, when each of the first types of LED chips 204 is an LED chip with a horizontal structure, an area A2 of each of the first fluorescent layers is either greater than or equal to an area A1 of the LED chip with the horizontal structure wherein the two electrodes of the LED chip with the horizontal structure are disposed in the same side of the LED chip. The LED chip with the horizontal structure is a transparent substrate served as a lining layer and thus, the LED chip with the horizontal structure is in transparent status such that the light is emitted from the lateral side. Therefore, when the area A2 of each of the first fluorescent layers 206 is either greater than or equal to an area A1 of the LED chip with the vertical structure, more light with warm white characteristic are generated. In one preferred embodiment, the area A1 of the first types of LED chips with the horizontal structure is 1 time to 2 times an area of each of the first fluorescent layers. In this case of FIG. 2 and FIG. 3, the area A1 is equal to the area A2.

Thus, the dimmable LED packaging structure is applicable to the LED chips with the vertical structure and/or the horizontal structure wherein an area A2 of each of the first fluorescent layers is 0.8 time to 2 times, but not limited to lower time or higher times, an area A1 of the first types of LED chips.

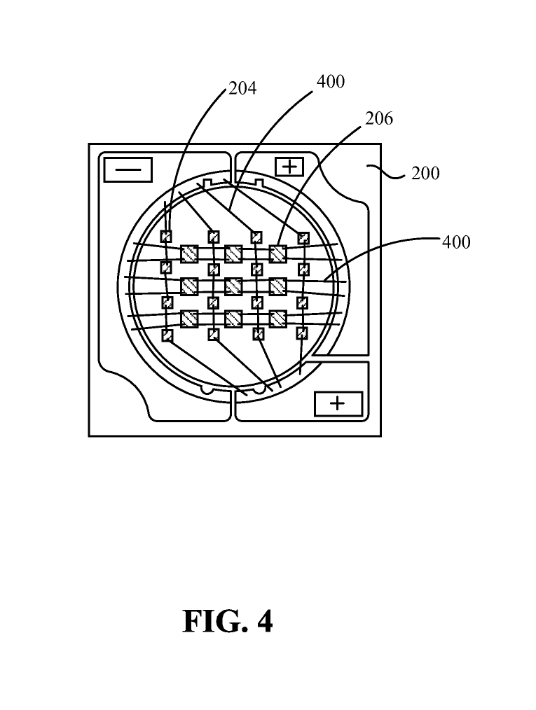

FIG. 4 is a schematic view of the wiring arrangement of the dimmable LED packaging structure according to one embodiment of the present invention. The first types of LED chips 204 sequentially includes N-type semiconductor layer, semiconductor emitting layer, P-type semiconductor layer wherein the N-type semiconductor layer may be N-type GaN layer, semiconductor emitting layer may be semiconductor with GaN or indium gallium nitride, and the P-type semiconductor layer may be P-type GaN layer. The N-type GaN layer and P-type GaN layer are electrically connected to the positive electrode and negative electrode respectively of the external power source by wiring 400 so that the first types of LED chips 204 turn on and thus electron-hole pairs of the semiconductor layer make the composite actions by the forward biasing voltage and the semiconductor emitting layer emits the light ray.

The dimmable LED packaging structure further includes encapsulating glue (not shown), e.g. silicon resin or epoxy, having higher transparent property and electrical insulation for covering the annual sidewall 202 and the second fluorescent layer 208 and for enclosing the dimmable LED packaging structure.

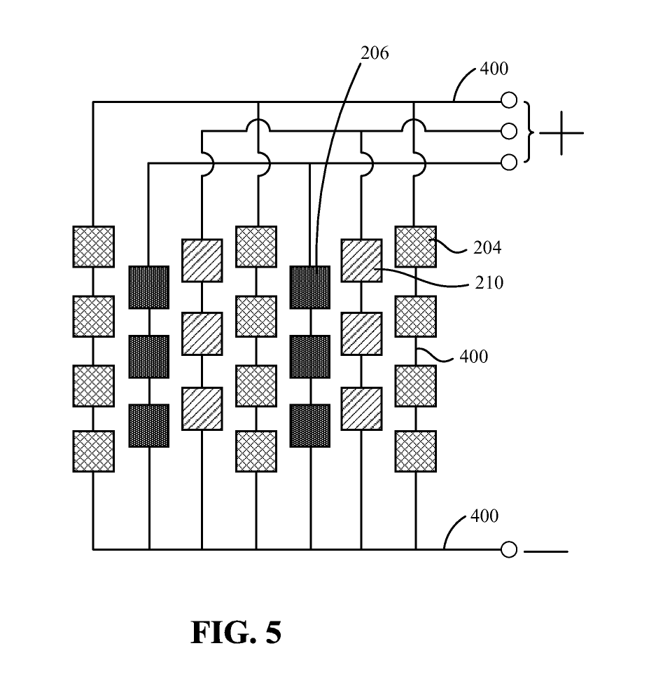

FIG. 5 is a schematic view of the wiring arrangement of the LED packaging structure according to another embodiment of the present invention. A plurality of second types of LED chips 210 are disposed on the substrate 200 within the annual sidewall 202 and staggered with the first types of LED chips 204. In one embodiment, the second types of LED chips 210 in the chip attachment region within the annual sidewall 202 are red LED chips to improve the color rendering index (CRI) of the dimmable LED packaging structure. In other words, the amount of the red LED chip and distribution status can be controller to adjust the CRI to reduce the light attenuation effect of the red LED chip. In one preferred embodiment, a ratio of an amount of the blue LED chips and an amount of the red LED chips is between one-to-one and three-to-one, but not limited, and between arbitrary values of the ratio.

According to the above-mentioned descriptions, the dimmable LED packaging structure employs a plurality of first fluorescent layers disposed on one portion of the first types of LED chips correspondingly to solve the problems of color temperature irregular change and uneven mixing-light, and employs a second fluorescent layer for overlaying the first fluorescent layers and the other portion of the first types of LED chips to solve the problem of complicated manufacturing steps.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A dimmable light-emitted diode (LED) packaging structure, comprising:
a substrate;
an annual sidewall disposed on the substrate;
a plurality of first types of LED chips disposed on the substrate within the annual sidewall, wherein each of the first types of LED chips emits a light ray;
a plurality of first fluorescent layers disposed on one portion of the first types of LED chips correspondingly; and
a second fluorescent layer filled within the annual sidewall for overlaying the first fluorescent layers and the other portion of the first types of LED chips;
wherein when the one portion of the first types of LED chips emit the light rays through the first fluorescent layers and the second fluorescent layer and when the other portion of the first types of LED chips emit the light rays through the second fluorescent layer, the light rays on a surface of the first fluorescent layers are mixed with a surface of the other portion of the first types of LED chips for dimming the LED.

2. The dimmable LED packaging structure of claim 1, further comprising a plurality of second types of LED chips disposed on the substrate within the annual sidewall and staggered with the first types of LED chips.

3. The dimmable LED packaging structure of claim 2, wherein each of the first types of LED chips is a blue LED chip and each of the second types of LED chips is a red LED chip.

4. The dimmable LED packaging structure of claim 3, wherein a ratio of an amount of the blue LED chips and an amount of the red LED chips is between one-to-one and three-to-one.

5. The dimmable LED packaging structure of claim 1, wherein when each of the first types of LED chips is an LED chip with a vertical structure, an area of each of the first fluorescent layers is either less than or equal to an area of the LED chip with the vertical structure.

6. The dimmable LED packaging structure of claim 1, wherein when each of the first types of LED chips is an LED chip with a horizontal structure, an area of each of the first fluorescent layers is either greater than or equal to an area of the LED chip with the horizontal structure.

7. The dimmable LED packaging structure of claim 1, wherein an area of each of the first fluorescent layers is 0.8 time to 2 times an area of the first types of LED chips.

8. The dimmable LED packaging structure of claim 1, wherein each of the first fluorescent layers is a phosphor sheet with warm white characteristic.

9. The dimmable LED packaging structure of claim 1, wherein a bottom surface of each of the first fluorescent layers further comprises a laminating layer for adhering the first fluorescent layers to the one portion of the first types of LED chips correspondingly.

10. The dimmable LED packaging structure of claim 1, wherein the second fluorescent layer is phosphor glue with cold white characteristic.

11. A dimmable light-emitted diode (LED) packaging structure, comprising:
a substrate;
a plurality of first types of LED chips disposed on the substrate, wherein each of the first types of LED chips emits a light ray;
a plurality of first fluorescent layers disposed on one portion of the first types of LED chips correspondingly; and
a second fluorescent layer on the substrate for overlaying the first fluorescent layers and the other portion of the first types of LED chips;
wherein when the one portion of the first types of LED chips emit the light rays through the first fluorescent layers and the second fluorescent layer and when the other portion of the first types of LED chips emit the light rays through the second fluorescent layer, the light rays on a surface of the first fluorescent layers are mixed with a surface of the other portion of the first types of LED chips for dimming the LED.

12. The dimmable LED packaging structure of claim 11, further comprising a plurality of second types of LED chips disposed on the substrate and staggered with the first types of LED chips.

13. The dimmable LED packaging structure of claim 12, wherein each of the first types of LED chips is a blue LED chip and each of the second types of LED chips is a red LED chip.

14. The dimmable LED packaging structure of claim 13, wherein a ratio of an amount of the blue LED chips and an amount of the red LED chips is between one-to-one and three-to-one.

15. The dimmable LED packaging structure of claim 11, wherein when each of the first types of LED chips is an LED chip with a vertical structure, an area of each of the first fluorescent layers is either less than or equal to an area of the LED chip with the vertical structure.

16. The dimmable LED packaging structure of claim 11, wherein when each of the first types of LED chips is an LED chip with a horizontal structure, an area of each of the first fluorescent layers is either greater than or equal to an area of the LED chip with the horizontal structure.

17. The dimmable LED packaging structure of claim 11, wherein an area of each of the first fluorescent layers is 0.8 time to 2.0 times an area of the first types of LED chips.

18. The dimmable LED packaging structure of claim 11, wherein each of the first fluorescent layers is a phosphor sheet with warm white characteristic.

19. The dimmable LED packaging structure of claim 11, wherein a bottom surface of each of the first fluorescent layers further comprises a laminating layer for adhering the first fluorescent layers to the one portion of the first types of LED chips correspondingly.

20. The dimmable LED packaging structure of claim 11, wherein the second fluorescent layer is phosphor glue with cold white characteristic.
